(19) United States
(12) Patent Application Publication
(10) Pub. No.: US 2020/0185431 A1
(43) Pub. Date: Jun. 11, 2020

(54) DISPLAY PANEL PREPARATION METHOD AND DISPLAY PANEL

(71) Applicant: FENGYUN YANG, (US)

(72) Inventor: FENGYUN YANG, (US)

(21) Appl. No.: 16/349,988

(22) PCT Filed: Nov. 15, 2018
(86) PCT No.: PCT/CN2018/115609

§ 371 Date: May 15, 2019

(51) Int. Cl. H01L 27/12; G02F 1/1343; H01L 21/443; H01L 21/4757; H01L 21/027; H01L 29/423; G02F 1/1368; H01L 21/467; H01L 21/4763; H01L 29/786; H01L 29/66; G02F 1/1362

(52) U.S. Cl. CPC H01L 27/1288; G02F 2001/136295; G02F 1/13439; H01L 21/443; H01L 21/47573; H01L 27/124; H01L 21/0273; H01L 29/42384; G02F 1/1368; H01L 27/127; H01L 21/467; H01L 21/47635; H01L 27/1225; H01L 29/7869; H01L 29/66969; G02F 1/136286; G02F 2001/13685; H01L 27/1262

(57) ABSTRACT

The present application discloses a display panel preparation method and a display panel. The display panel preparation method includes: depositing a layer of metal, a buffer material, and an oxide in sequence on a substrate; and forming a first metal layer, a buffer layer, and an oxide film layer through etching by using a same mask.

The present application claims priority to Chinese Patent Application No. CN2018112304716, filed with the Chinese Patent Office on Oct. 22, 2018 and entitled “DISPLAY PANEL PREPARATION METHOD AND DISPLAY PANEL”, which is incorporated herein by reference in its entirety.

### TECHNICAL FIELD

The present application relates to the field of display technologies, and in particular, to a display panel preparation method and a display panel.

### BACKGROUND

The descriptions herein provide only background information related to the present application, and do not necessarily constitute the prior art.

Along with the development and advancement of technologies, the liquid crystal display becomes a main stream product of displays and is widely applied because of its features such as a thin body, power saving, and low radiation. Liquid crystal displays known to the inventor are mostly backlight liquid crystal displays. A backlight liquid crystal display includes a liquid crystal display panel and a backlight module. A working principle of the liquid crystal display panel is as follows: Liquid crystal molecules are placed between two parallel glass substrates, and driving voltage is applied to the two glass substrates to control a rotation direction of the liquid crystal molecules, so as to refract light of the backlight module to generate a picture.

Currently, the IGZO (indium gallium zinc oxide) technology has been widely studied and applied. There are three common IGZO structures: a BCE (back channel etch) structure, an ESL (etch stopper layer) structure, and a Self-aligned Top Gate structure. The BCE structure is back channel etched, and a back channel may be damaged, thereby affecting stability of a TFT component. In the ESL structure, a back channel can be protected; however, the ESL structure cannot be used as a short-channel structure, and there is relatively large parasitic capacitance. The top-gate type can be used as a short-channel structure, and there is extremely small parasitic capacitance, but one additional mask is needed.

### SUMMARY

A purpose of the present application is to provide a display panel preparation method and a display panel, to reduce mask processes of the display panel.

To achieve the foregoing purpose, the present application provides a display panel preparation method, including steps of:

forming a layer of metal, a buffer material, and an oxide in sequence on a substrate;

forming a first metal layer, a buffer layer, and an oxide film layer through etching by using a same mask;

forming a gate insulating layer, a gate layer, a source layer, and a drain layer on the oxide film layer; and

forming a passivation layer and a transparent electrode layer in sequence on the gate layer, the source layer, and the drain layer.

The present application discloses a display panel preparation method, including steps of:

forming a layer of metal, a buffer material, and an oxide in sequence on a substrate;

forming a first metal layer, a buffer layer, and an oxide film layer in sequence through etching by using a same mask;

forming, on the oxide film layer by using a half-tone mask, a gate insulating layer that includes a middle part, a first lateral part, a second lateral part, and a hollow part:

forming a second layer of metal by coating the gate insulating layer with metal through sputtering, and etching on the second layer of metal by using a same mask process, to obtain a gate layer, a source layer, and a drain layer, where the formed source layer and drain layer are connected by using the oxide film layer; and

forming a passivation layer and a transparent electrode layer in sequence on the gate layer, the source layer, and the drain layer; where

a thickness of the middle part of the gate insulating layer is greater than a thickness of the first lateral part, and the thickness of the middle part of the gate insulating layer is greater than a thickness of the second lateral part, and the hollow part is formed between the middle part and the first lateral part and between the middle part and the second lateral part; the gate layer is located on the middle part of the gate insulating layer, a width of the gate layer is less than a width of the middle part of the gate insulating layer, and the source layer and the drain layer are respectively located on the two lateral parts of the gate insulating layer, and the source layer and the drain layer are insulated from the gate layer.

The present application further discloses a display panel, including: a first substrate, where a first metal layer, a buffer layer, and an oxide film layer are disposed on the first substrate in sequence; a gate insulating layer, a gate layer, a source layer, and a drain layer, formed on the oxide film layer; and a passivation layer and a transparent electrode layer, formed in sequence on a second metal layer, where the first metal layer, the buffer layer, and the oxide film layer are formed by using a same mask process.

Optionally, the gate insulating layer is located on the oxide film layer; the gate insulating layer includes a middle part, a first lateral part, and a second lateral part, where a thickness of the middle part is greater than thicknesses of the first lateral part and the second lateral part; the gate insulating layer further includes a first hollow part that is formed between the middle part and the first lateral part and a second hollow part that is formed between the middle part and the second lateral part; the gate layer is formed on the middle part; the source layer is formed on the first lateral part and is connected to the oxide film layer by using the first hollow part; the drain layer is formed on the second lateral part and is connected to the oxide film layer by using the second hollow part; and the gate layer, the source layer, and the drain layer are formed by using a same metal layer and a same mask process.

This solution is different from a general design in that a top-gate structure is improved. The layer of metal, the buffer material, and the oxide are deposited on the substrate in sequence; and then the first metal layer, the buffer layer, and the oxide film layer are formed through etching by using a same mask. In comparison with a process in which the first metal layer, the buffer layer, and the oxide film layer are formed separately by using different masks, this solution reduces at least one mask and saves time of at least one exposing and developing process, thereby achieving the purpose of reducing costs and improving a capacity.

### BRIEF DESCRIPTION OF DRAWINGS

The drawings are included to provide further understanding of embodiments of the present application, which constitute a part of the specification and illustrate the embodiments of the present application, and describe the principles of the present application together with the text description. Apparently, the accompanying drawings in the following description show merely some embodiments of the present application, and a person of ordinary skill in the art may still derive other accompanying drawings from these accompanying drawings without creative efforts. In the accompanying drawings:

FIG. 1a to FIG. 1g are schematic diagrams of seven mask processes of a display panel according to an embodiment of the present application;

FIG. 2a to FIG. 2e are schematic diagrams of five mask processes of a display panel according to an embodiment of the present application;

FIG. 3a to FIG. 3f are schematic diagrams of six mask processes of a display panel according to an embodiment of the present application;

FIG. 4 is a schematic flowchart (1) of a display panel preparation method according to an embodiment of the present application; and

FIG. 5 is a schematic flowchart (2) of a display panel preparation method according to an embodiment of the present application.

### DETAILED DESCRIPTION

The specific structure and function details disclosed herein are merely representative, and are intended to describe exemplary embodiments of the present application. However, the present application can be specifically embodied in many alternative forms, and should not be interpreted to be limited to the embodiments described herein.

In the description of the present application, it should be understood that, orientation or position relationships indicated by the terms “center”, “transversal”, “upper”, “lower”, “left”, “right”, “vertical”, “horizontal”, “top”, “bottom”, “inner”, “outer”, etc. are based on the orientation or position relationships as shown in the drawings, for ease of the description of the present application and simplifying the description only, rather than indicating or implying that the indicated device or element must have a particular orientation or be constructed and operated in a particular orientation. Therefore, these terms should not be understood as a limitation to the present application. In addition, the terms such as “first” and “second” are merely for a descriptive purpose, and cannot be understood as indicating or implying relative importance, or implicitly indicating the number of the indicated technical features. Hence, the features defined by “first” and “second” can explicitly or implicitly include one or more features. In the description of the present application, “a plurality of” means two or more, unless otherwise stated. In addition, the term “include” and any variations thereof are intended to cover a non-exclusive inclusion.

In the description of the present application, it should be understood that, unless otherwise specified and defined, the terms “install”, “connected with”, “connected to” should be comprehended in a broad sense. For example, these terms may be comprehended as being fixedly connected, detachably connected or integrally connected; mechanically connected or electrically connected; or directly connected or indirectly connected through an intermediate medium, or in an internal communication between two elements. The specific meanings about the foregoing terms in the present application may be understood by those skilled in the art according to specific circumstances.

The terms used herein are merely for the purpose of describing the specific embodiments, and are not intended to limit the exemplary embodiments. As used herein, the singular forms “a”, “an” are intended to include the plural forms as well, unless otherwise indicated in the context clearly. It will be further understood that the terms “comprise” and/or “include” used herein specify the presence of the stated features, integers, steps, operations, elements and/or components, but do not preclude the presence or addition of one or more other features, integers, steps, operations, elements, components and/or combinations thereof.

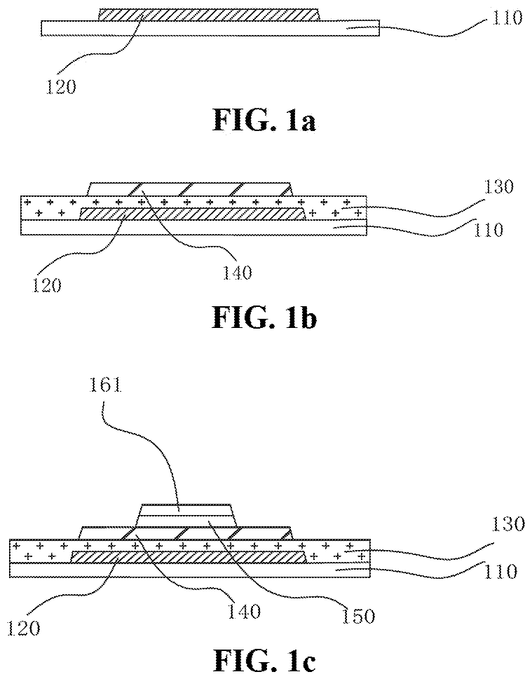

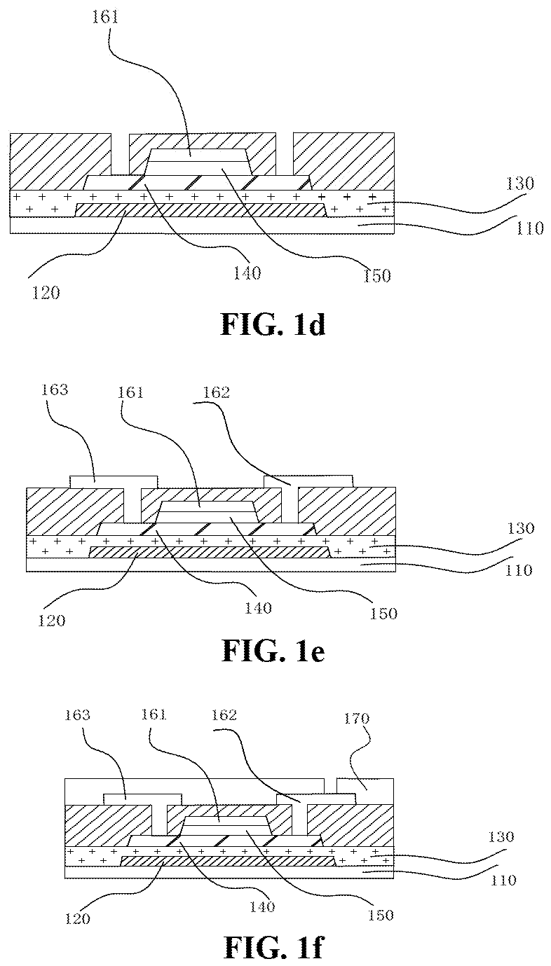

Referring to FIG. 1a, a first metal layer 120 is formed on a glass substrate 110 by using a one-mask process.

Referring to FIG. 1b, a buffer deposit layer is deposited and formed on the first metal layer 120, and an oxide film deposit layer is deposited and formed on the buffer deposit layer. An oxide film layer 140 and a buffer layer 130 that covers all around the first metal layer 120 are obtained through etching on the buffer deposit layer and the oxide film deposit layer by using a same mask process.

Referring to FIG. 1c, a gate insulating deposit layer is deposited and formed on the oxide film layer 140 and a gate metal layer is deposited and formed on the gate insulating deposit layer; and a gate insulating layer 150 and a gate layer 161 are formed through etching on the gate insulating deposit layer and the gate metal layer by using one mask process.

Referring to FIG. 1d, an interconnection layer 160 that includes a middle part 151, a first lateral part 152, a second lateral part 153, and a hollow part is formed on the oxide film layer 140 by using one mask, where the hollow part is formed between the middle part 151 and the first lateral part 152 and between the middle part 151 and the second lateral part 153.

Referring to FIG. 1e, a second layer of metal is formed on the interconnection layer 160, and a drain layer 163 and a source layer 162 are obtained through etching on the second layer of metal by using a same mask process.

Referring to FIG. 1f, a passivation layer 170 is obtained through etching on the drain layer 163 and the source layer 162 by using one mask process.

Referring to FIG. 1g, a transparent electrode layer 180 is obtained through etching on the passivation layer 170 by using one mask.

Seven masks are used in total.

The following further describes the present application with reference to accompanying drawings and optional embodiments.

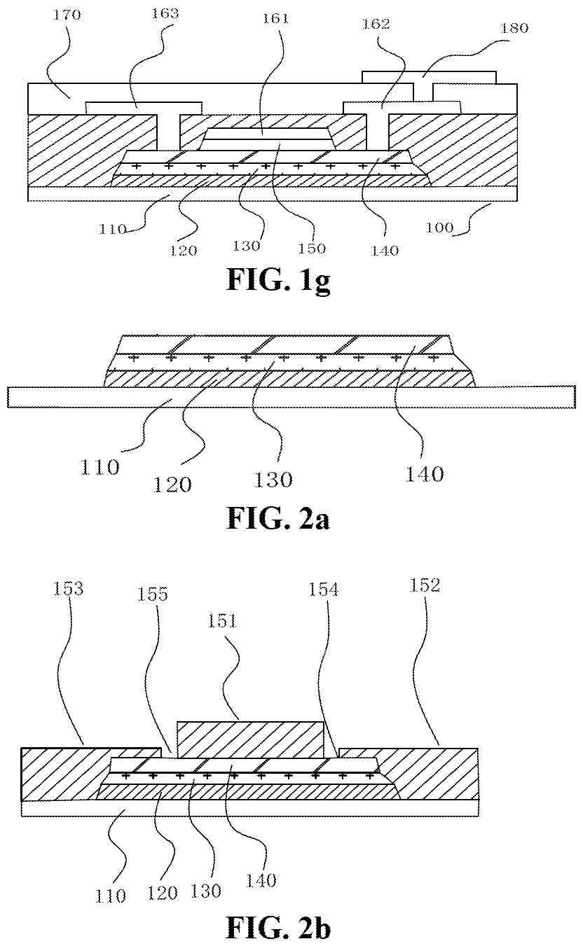

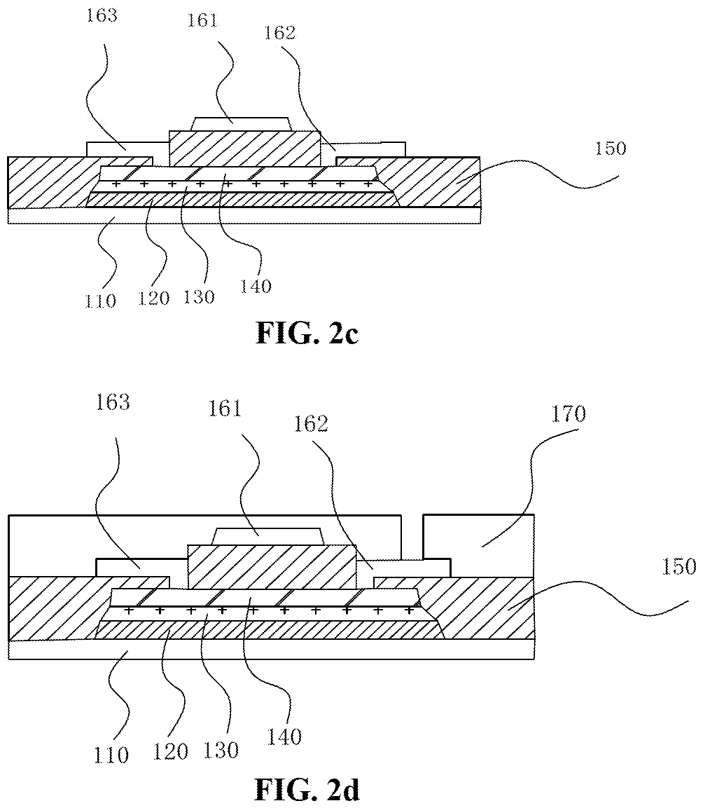

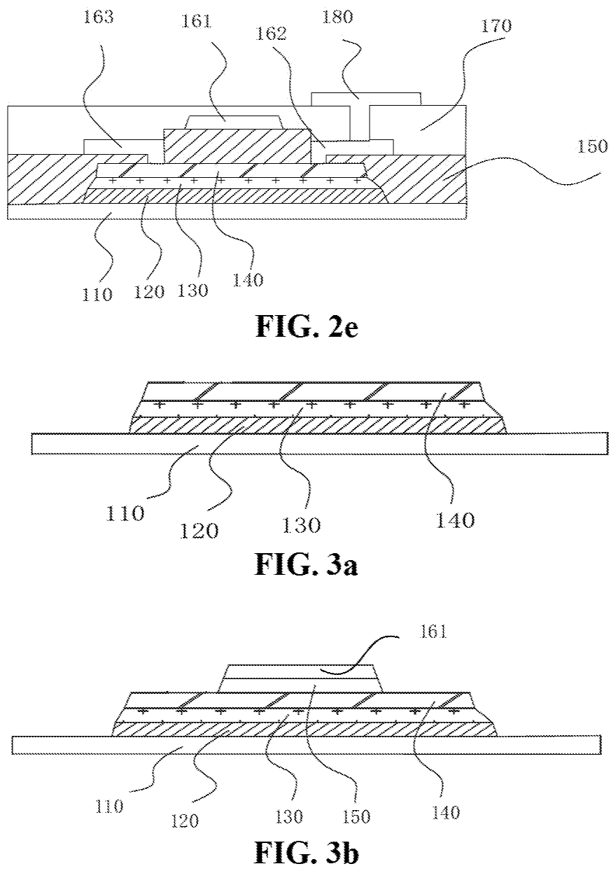

As shown in FIG. 2a to FIG. 4, an embodiment of the present application discloses a method for preparing a display panel 100. The method includes the following steps:

S41: Depositing a layer of metal, a buffer material, and an oxide in sequence on a substrate 110, and form a first metal layer 120, a buffer layer 130, and an oxide film layer 140 through etching by using a same mask;

S42: Forming a gate insulating layer 150, a gate layer 161, a source layer 162, and a drain layer 163 on the oxide film layer 140;

S43: Forming a passivation layer 170 and a transparent electrode layer 180 in sequence on the gate layer 161, the source layer 162, and the drain layer 163.

The substrate 110 is a glass substrate 110.

In this solution, a self-aligned top-gate structure is improved. The layer of metal, the buffer material, and the oxide are deposited on the substrate 110 in sequence, and then the first metal layer 120, the buffer layer 130, and the oxide film layer 140 are formed through etching by using a same mask. In comparison with a process in which the first metal layer 120, the buffer layer 130, and the oxide film layer 140 are formed separately by using different masks, one mask is reduced, that is, seven masks are changed to six masks. This saves time of one exposing and developing process, thereby achieving the purpose of reducing costs and improving a capacity.

In a general example solution, a seven-mask process is used. However, in the present application, the first metal layer 120, the buffer layer 130, and the oxide film layer 140 are formed through etching by using a same mask. Therefore, one mask process is reduced relative to the example solution.

In one or more embodiments, as shown in FIG. 2b to FIG. 2c, the step of forming a gate insulating layer 150, a gate layer 161, a source layer 162, and a drain layer 163 on the oxide film layer 140 includes:

forming on the oxide film layer 140 by using a half-tone mask, a gate insulating layer 150 that includes a middle part 151, a first lateral part 152, a second lateral part 153, and a hollow part;

forming a second layer of metal by coating the gate insulating layer 150 with metal through sputtering, and etching on the second layer of metal by using a same mask process, to obtain the gate layer 161, the source layer 162, and the drain layer 163, where

a thickness of the middle part 151 of the gate insulating layer 150 is greater than a thickness of the first lateral part 152, and the thickness of the middle part 151 of the gate insulating layer 150 is greater than a thickness of the second lateral part 153, and the hollow part is formed between the middle part 151 and the first lateral part 152 and between the middle part 151 and the second lateral part 153; and the formed source layer 162 and drain layer 163 are connected by using the oxide film layer 140.

In this solution, the second layer of metal is formed by coating the gate insulating layer 150 with metal through sputtering, and the gate layer 161, the source layer 162, and the drain layer 163 are obtained through etching on the second layer of metal by using a same mask process. This further reduces used masks and further reduces processes, thereby greatly improving production efficiency and achieving the purpose of reducing costs and improving a capacity.

In the present application, one mask process is reduced, relative to the seven-mask process in the general example, by forming the first metal layer 120, the buffer layer 130, and the oxide film layer 140 through etching by using a same mask. On such a basis, the gate layer 161, the source layer 162, and the drain layer 163 are further obtained through etching on the second layer of metal by using a same mask process. This further reduces mask processes and further improves production efficiency, thereby achieving the purpose of better reducing costs and improving a capacity.

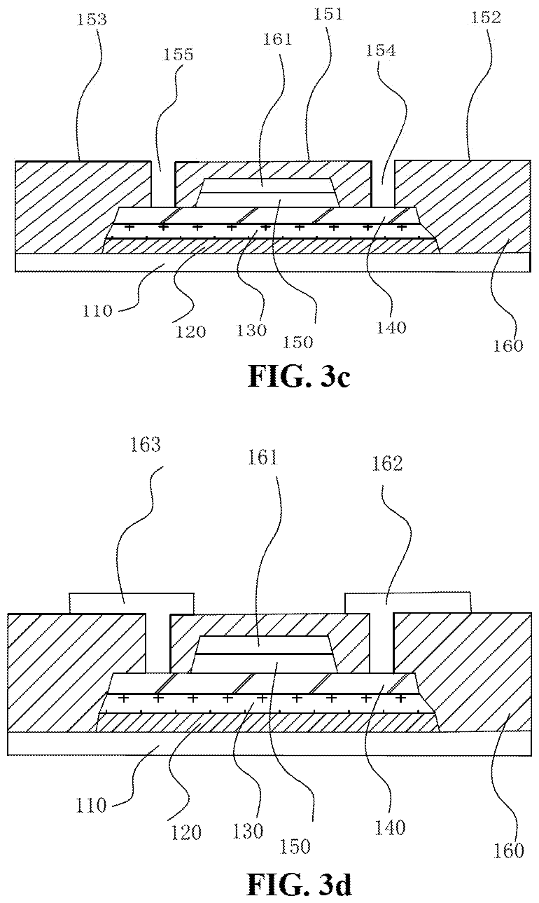

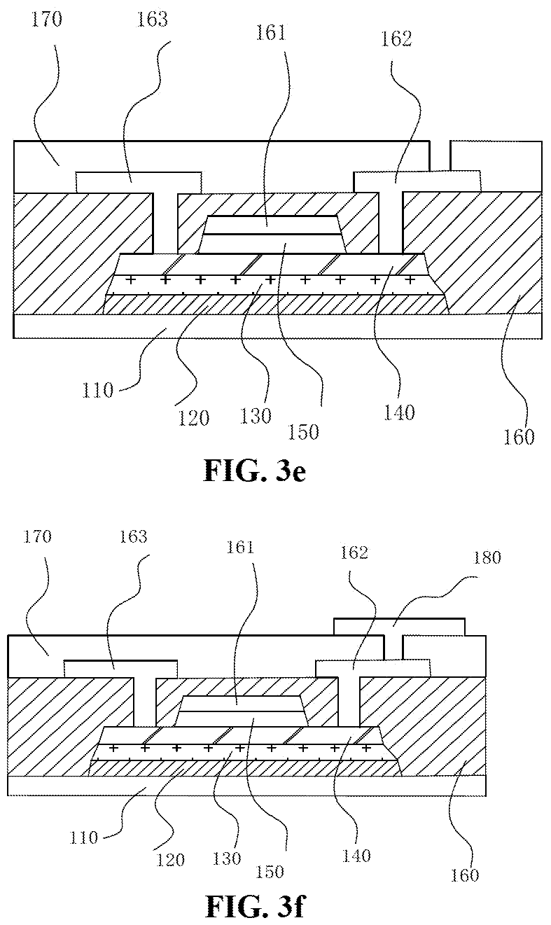

In one or more embodiments, as shown in FIG. 3b to FIG. 3d, the step of forming a gate insulating layer 150, a gate layer 161, a source layer 162, and a drain layer 163 on the oxide film layer 140 includes:

depositing on the oxide film layer 140 to form a gate insulating deposit layer, and depositing on the gate insulating deposit layer to form a gate metal layer;

etching on the gate insulating deposit layer and the gate metal layer by using one mask process, to form the gate insulating layer 150 and the gate layer 161;

forming, on the oxide film layer 140 by using one mask, an interconnection layer 160 that includes a middle part 151, a first lateral part 152, a second lateral part 153, and a hollow part; and

forming a second layer of metal on the interconnection layer 160, and etching on the second layer of metal to obtain the drain layer 163 and the source layer 162, where

the hollow part is formed between the middle part 151 and the first lateral part 152 and between the middle part 151 and the second lateral part 153.

In this solution, the gate layer 161 is first formed, and then the source layer 162 and the drain layer 163 are formed. The source layer 162 and the drain layer 163 are formed on a same layer, and are not located on a same layer as the gate layer 161.

In this way, the source layer 162 and the drain layer 163 can be insulated from the gate layer 161. The interconnection layer 160 includes the middle part 151, the first lateral part 152, the second lateral part 153, and the hollow part. Disposition of the hollow part can prevent a short circuit, ensure insulation, and ensure switching performance of a TFT.

In one or more embodiments, referring to FIG. 2a, the step of forming a first metal layer 120, a buffer layer 130, and an oxide film layer 140 on the substrate 110 through etching by using a same mask includes:

forming a photoresist layer with a preset pattern on an oxide film deposit layer by using one mask;

etching on a section that is of two lateral parts of the oxide film deposit layer and that does not overlap with the photoresist layer, to obtain the oxide film layer 140:

etching on a section that is of two lateral parts of the buffer layer 130 and that does not overlap with the oxide film layer 140, to obtain the buffer layer 130;

etching on a section that is of two lateral parts of the first metal layer 120 and that does not overlap with the buffer layer 130, to obtain the first metal layer 120; and

peeling off the photoresist layer from the oxide film layer 140.

In fact, due to etching, the buffer layer 130 is slightly larger than the oxide film layer 140, and the first metal layer 120 is slightly larger than the buffer layer 130. All these are normal; or even, the buffer layer 130 may also be designed to be larger than the oxide film layer 140 and the first metal layer 120 larger than the buffer layer 130.

The first metal layer 120, the buffer layer 130, and the oxide film layer 140 are formed by using a same mask process, and a blocking layer is formed on the first metal layer 120, the buffer layer 130, and the oxide film layer 140. Then, different etchants can be used to respectively etch on the first metal layer 120, the buffer layer 130, and the oxide film layer 140. The blocking layer is removed after the etching is completed. This further reduces used masks, thereby achieving the purpose of reducing costs and improving a capacity.

In one or more embodiments, as shown in FIG. 2c, in the step of forming a second layer of metal on the gate insulating layer 150, and obtaining the gate layer 161, the source layer 162, and the drain layer 163 through etching by using a same mask process, the gate layer 161 is located on the middle part 151 of the gate insulating layer 150, a width of the gate layer 161 is less than a width of the middle part 151 of the gate insulating layer 150, and the source layer 162 and the drain layer 163 are respectively located on the two lateral parts of the gate insulating layer 150, and the source layer 162 and the drain layer 163 are insulated from the gate layer 161.

In this solution, the gate layer 161 is located on and overlaps with the middle part 151 of the gate insulating layer 151, and the width of the gate layer 161 is less than the width of the middle part 150 of the gate insulating layer 150. The source layer 162 and the drain layer 163 are respectively located on the two lateral parts of gate insulating layer 150. This can reduce parasitic capacitance generated between the gate layer 161 and the drain layer 163 and reduce parasitic capacitance generated between the gate layer 161 and the source layer 162.

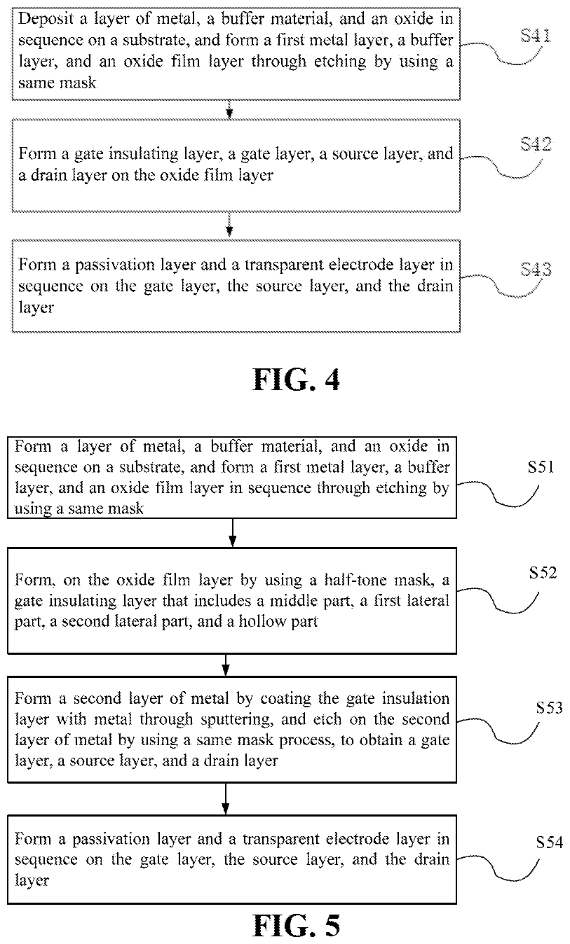

In another embodiment of the present application, as shown in FIG. 2a to FIG. 2e and FIG. 4, a method for preparing a display panel 100 is disclosed and includes the following steps:

S51: Forming a layer of metal, a buffer material, and an oxide in sequence on a substrate 110; and form a first metal layer 120, a buffer layer 130, and an oxide film layer 140 in sequence through etching by using a same mask;

S52: Forming on the oxide film layer 140 by using a half-tone mask, a gate insulating layer 150 that includes a middle part 151, a first lateral part 152, a second lateral part 153, and a hollow part, where a thickness of the middle part 151 of the gate insulating layer 150 is greater than a thickness of the first lateral part 152, and the thickness of the middle part 151 of the gate insulating layer 150 is greater than a thickness of the second lateral part 153, and the hollow part is formed between the middle part 151 and the first lateral part 152 and between the middle part 151 and the second lateral part 153;

S53: Forming a second layer of metal by coating the gate insulation layer 150 with metal through sputtering, and etch on the second layer of metal by using a same mask process, to obtain a gate layer 161, a source layer 162, and a drain layer 163, where the formed source layer 162 and drain layer 163 are connected by using the oxide film layer 140, the gate layer 161 is located on the middle part 151 of the gate insulating layer 150, a width of the gate layer 161 is less than a width of the middle part 151 of the gate insulating layer 150, and the source layer 162 and the drain layer 163 are respectively located on the two lateral parts of the gate insulating layer 150, and the source layer 162 and the drain layer 163 are insulated from the gate layer 161;

S54: Forming a passivation layer 170 and a transparent electrode layer 180 in sequence on the gate layer 161, the source layer 162, and the drain layer 163.

In this solution, the second layer of metal is formed by coating the gate insulating layer 150 with metal through sputtering, and the gate layer 161, the source layer 162, and the drain layer 163 are obtained through etching on the second layer of metal by using a same mask process. This further reduces used masks and further reduces processes, and the solution of the present application can be implemented by using five masks, thereby greatly improving production efficiency and achieving the purpose of reducing costs and improving a capacity. In addition, the source layer 162 and the drain layer 163 are before the gate layer 161; and disposition of a segment gap structure and the hollow part can prevent a short circuit, ensure insulation, and ensure switching performance of a TFT.

In the present application, one mask process is reduced, relative to the seven-mask process in the general example, by forming the first metal layer 120, the buffer layer 130, and the oxide film layer 140 through etching by using a same mask. On such a basis, the gate layer 161, the source layer 162, and the drain layer 163 are further obtained through etching on the second layer of metal by using a same mask process. This further reduces mask processes and further improves production efficiency, thereby achieving the purpose of better reducing costs and improving a capacity.

In another embodiment of the present application, as shown in FIG. 3a, a display panel 100 is disclosed, including:

a first substrate 110, where a first metal layer 120, a buffer layer 130, and an oxide film layer 140 are disposed on the first substrate 110 in sequence; a gate insulating layer 150, a gate layer 161, a source layer 162, and a drain layer 163, formed on the oxide film layer 140; and a passivation layer 170 and a transparent electrode layer 180, formed in sequence on a second metal layer, where the first metal layer 120, the buffer layer 130, and the oxide film layer 140 are formed by using a same mask process.

In this solution, the first metal layer 120, the buffer layer 130, and the oxide film layer 140 are formed by using a same mask. In comparison with a process in which the first metal layer 120, the buffer layer 130, and the oxide film layer 140 are formed separately by using different masks, one mask is reduced, that is, seven masks are changed to six masks. This saves time of one exposing and developing process, thereby achieving the purpose of reducing costs and improving a capacity.

In one or more embodiments, as shown in FIG. 2c, the gate insulating layer 150 is located on the oxide film layer 140; the gate insulating layer 150 includes a middle part 151, a first lateral part 152, and a second lateral part 153, where a thickness of the middle part 151 is greater than thicknesses of the first lateral part 152 and the second lateral part 153; the gate insulating layer 150 further includes a first hollow part 154 that is formed between the middle part 151 and the first lateral part 152 and a second hollow part 155 that is formed between the middle part 151 and the second lateral part 153; the gate layer 161 is formed on the middle part 151; the source layer 162 is formed on the first lateral part 152 and is connected to the oxide film layer 140 by using the first hollow part 154; the drain layer 163 is formed on the second lateral part 153 and is connected to the oxide film layer 140 by using the second hollow part 155; and the gate layer 161, the source layer 162, and the drain layer 163 are formed by using a same metal layer by using a same one-mask process.

In this solution, the second layer of metal is formed by coating the gate insulating layer 150 with metal through sputtering, and the gate layer 161, the source layer 162, and the drain layer 163 are obtained through etching on the second layer of metal by using a same mask process. This further reduces used masks and further reduces processes, and the solution of the present application can be implemented by using five masks, thereby greatly improving production efficiency and achieving the purpose of reducing costs and improving a capacity.

In one or more embodiments, as shown in FIG. 3b to FIG. 3d, the gate insulating layer 150 is located on a middle part 151 of the oxide film layer 140; the gate layer 161 is located on the gate insulating layer 150; an interconnection layer 160 is located on the oxide film layer 140; the interconnection layer 160 includes a middle part 151, a first lateral part 152, and a second lateral part 153, where a first hollow part 154 is formed between the middle part 151 and the first lateral part 152 and a second hollow part 155 is formed between the middle part 151 and the second lateral part 153; the source layer 162 is located on the first lateral part 152 and the middle part 151, and is connected to the oxide film layer 140 by using the first hollow part 154; the drain layer 163 is located on the second lateral part 153 and the middle part 151, and is connected to the oxide film layer 140 by using the second hollow part 155; and the source layer 162 and the drain layer 163 are formed by using a same metal layer and a same mask process.

In this solution, the gate layer 161 is first formed, and then the source layer 162 and the drain layer 163 are formed. The source layer 162 and the drain layer 163 are formed on a same layer, and are not located on a same layer as the gate layer 161. In this way, the source layer 162 and the drain layer 163 can be insulated from the gate layer 161. The interconnection layer 160 includes the middle part 151, the first lateral part 152, the second lateral part 153, and the hollow part. Disposition of the hollow part can prevent a short circuit, ensure insulation, and ensure switching performance of a TFT.

In one or more embodiments, a width of the gate layer 161 is less than a width of the middle part 151 of the gate insulating layer 150, the source layer 162 and the drain layer 163 are insulated from the gate layer 161, and the source layer 162 and the drain layer 163 are connected by using the oxide film layer 140.

In this solution, the width of the gate layer 161 is less than the width of the middle part 151 of the gate insulating layer 150, and the source layer 162 and the drain layer 163 are respectively located on the two lateral parts of the gate insulating layer 150. This can reduce parasitic capacitance generated between the gate layer 161 and the drain layer 163 and reduce parasitic capacitance generated between the gate layer 161 and the source layer 162.

It should be noted that the limitation on the steps in this solution may be not considered as a limitation to a sequence of the steps provided that implementation of a specific solution is not affected. A step appears first may be first performed or may be performed later, or even steps may be performed at a same time. All these cases shall be considered as falling within the protection scope of the present application provided that this solution can be implemented.

The panel in the present application may be a TN panel (full spelling: Twisted Nematic, that is, twisted nematic panel), an IPS (In-Plane Switching, in-plane switching) panel, or a VA_panel (Multi-domain Vertical Alignment, multi-domain vertical alignment technology). Certainly, the panel in the present application may be a panel of another type, provided that it is applicable.

The foregoing contents are further detailed descriptions of the present application in combination with specific implementations, and it cannot be construed that specific implementations of the present application are only restricted to these descriptions. A person with ordinary skills in the art of the present application may still make several simple deductions or replacements without departing from the concepts of the present application. All such deductions and replacements shall be considered to fall within the protection scope of the present application.

1. A display panel preparation method, comprising:
depositing a layer of metal, a buffer material, and an oxide in sequence on a substrate, and forming a first metal layer, a buffer layer, and an oxide film layer through etching by using a same mask;
forming a gate insulating layer, a gate layer, a source layer, and a drain layer on the oxide film layer; and
forming a passivation layer and a transparent electrode layer in sequence on the gate layer, the source layer, and the drain layer.

2. The display panel preparation method according to claim 1, wherein the step of forming a gate insulating layer, a gate layer, a source layer, and a drain layer on the oxide film layer comprises:
forming on the oxide film layer by using a half-tone mask, a gate insulating layer that comprises a middle part, a first lateral part, a second lateral part, and a hollow part; and
forming a second layer of metal by coating the gate insulating layer with metal through sputtering, and etching on the second layer of metal by using a same mask process, to obtain the gate layer, the source layer, and the drain layer, wherein
a thickness of the middle part of the gate insulating layer is greater than a thickness of the first lateral part, and the thickness of the middle part of the gate insulating layer is greater than a thickness of the second lateral part,
the hollow part is formed between the middle part and the first lateral part and between the middle part and the second lateral part; and
the formed source layer and drain layer are connected by using the oxide film layer.

3. The display panel preparation method according to claim 1, wherein the step of forming a gate insulating layer, a gate layer, a source layer, and a drain layer on the oxide film layer comprises:
depositing on the oxide film layer to form a gate insulating deposit layer, and depositing on the gate insulating deposit layer to form a gate metal layer,
etching on the gate insulating deposit layer and the gate metal layer by using one mask process, to form the gate insulating layer and the gate layer;
forming on the oxide film layer by using one mask, an interconnection layer that comprises a middle part, a first lateral part, a second lateral part, and a hollow part; and
forming a second layer of metal on the interconnection layer, and etching on the second layer of metal to obtain the drain layer and the source layer, wherein
the hollow part is formed between the middle part and the first lateral part and between the middle part and the second lateral part.

4. The display panel preparation method according to claim 1, wherein the step of forming a first metal layer, a buffer layer, and an oxide film layer on a substrate through etching by using a same mask comprises:
forming a photoresist layer with a preset pattern on an oxide film deposit layer by using one mask;
etching on a section that is of two lateral parts of the oxide film deposit layer and that does not overlap with the photoresist layer, to obtain the oxide film layer;
etching on a section that is of two lateral parts of a buffer deposit layer and that does not overlap with the oxide film layer, to obtain the buffer layer;
etching on a section that is of two lateral parts of a first layer of met and that does not overlap with the buffer layer, to obtain the first metal layer; and
peeling off the photoresist layer from the oxide film layer.

5. The display panel preparation method according to claim 4, wherein a width of the buffer layer is greater than a width of the oxide film layer.

6. The display panel preparation method according to claim 4, wherein a width of the first metal layer is greater than a width of the buffer layer.

7. The display panel preparation method according to claim 2, wherein in the step of forming a second layer of metal by coating the gate insulating layer with metal through sputtering, and etching on the second layer of metal by using a same mask process, to obtain the gate layer, the source layer, and the drain layer,
the gate layer is located on the middle part of the gate insulating layer;
a width of the gate layer is less than a width of the middle part of the gate insulating layer, and the source layer and the drain layer are respectively located on the two lateral parts of the gate insulating layer; and
the source layer and the drain layer are insulated from the gate layer.

8. The display panel preparation method according to claim 1, wherein the substrate is a glass substrate.

9. A display panel preparation method, comprising:
forming a layer of metal, a buffer material, and an oxide in sequence on a substrate;
forming a first metal layer, a buffer layer, and an oxide film layer in sequence through etching by using a same mask;
forming, on the oxide film layer by using a half-tone mask, a gate insulating layer that comprises a middle part, a first lateral part, a second lateral part, and a hollow part;
forming a second layer of metal by coating the gate insulating layer with metal through sputtering, and etching on the second layer of metal by using a same mask process, to obtain a gate layer, a source layer, and a drain layer, wherein the formed source layer and drain layer are connected by using the oxide film layer; and
forming a passivation layer and a transparent electrode layer in sequence on the gate layer, the source layer, and the drain layer; wherein
a thickness of the middle part of the gate insulating layer is greater than a thickness of the first lateral part, and the thickness of the middle part of the gate insulating layer is greater than a thickness of the second lateral part,
the hollow part is formed between the middle part and the first lateral part and between the middle part and the second lateral part;
the gate layer is located on the middle part of the gate insulating layer,
a width of the gate layer is less than a width of the middle part of the gate insulating layer, and the source layer and the drain layer are respectively located on the two lateral parts of the gate insulating layer, and
the source layer and the drain layer are insulated from the gate layer.

10. A display panel, comprising:
a first substrate, wherein a first metal layer, a buffer layer, and an oxide film layer are disposed on the first substrate in sequence;
a gate insulating layer, a gate layer, a source layer, and a drain layer, formed on the oxide film layer; and
a passivation layer and a transparent electrode layer, formed in sequence on a second metal layer, wherein
the first metal layer, the buffer layer, and the oxide film layer are formed by using a same mask process.

11. The display panel according to claim 10, wherein the first substrate is a glass substrate.

12. The display panel according to claim 10, wherein a width of the buffer layer is greater than a width of the oxide film layer.

13. The display panel according to claim 10, wherein a width of the first metal layer is greater than a width of the buffer layer.

14. The display panel according to claim 10, wherein the gate insulating layer is located on the oxide film layer;
the gate insulating layer comprises a middle part, a first lateral part, and a second lateral part, wherein a thickness of the middle part is greater than thicknesses of the first lateral part and the second lateral part;
the gate insulating layer further comprises a first hollow part that is formed between the middle part and the first lateral part and a second hollow part that is formed between the middle part and the second lateral part;
the gate layer is formed on the middle part;
the source layer is formed on the first lateral part and is connected to the oxide film layer by using the first hollow part;
the drain layer is formed on the second lateral part and is connected to the oxide film layer by using the second hollow part; and
the gate layer, the source layer, and the drain layer are formed by using a same metal layer and a same mask process.

15. The display panel according to claim 10, wherein the gate insulating layer is located on a middle part of the oxide film layer;
the gate layer is located on the gate insulating layer;
an interconnection layer is located on the oxide film layer;
the interconnection layer comprises a middle part, a first lateral part, and a second lateral part, wherein a first hollow part is formed between the middle part and the first lateral part and a second hollow part is formed between the middle part and the second lateral part;
the source layer is located on the first lateral part and the middle part, and is connected to the oxide film layer by using the first hollow part;
the drain layer is located on the second lateral part and the middle part, and is connected to the oxide film layer by using the second hollow part; and
the source layer and the drain layer are formed by using a same metal layer and a same mask process.

16. The display panel according to claim 14, wherein a width of the gate layer is less than a width of the middle part of the gate insulating layer, the source layer and the drain layer are insulated from the gate layer, and the source layer and the drain layer are connected by using the oxide film layer.

17. The display panel according to claim 10, wherein the display panel is one of a twisted nematic display panel, an in-plane switching display panel, or a multi-domain vertical alignment.
